(19) United States
(12) Patent Application Publication
(10) Pub. No.: US 2014/0299903 A1
(43) Pub. Date: Oct. 9, 2014

(54) DOUBLE-CHIP LIGHT EMITTING DIODE

(71) Applicant: UNITY OPTO TECHNOLOGY CO., LTD., NEW TAIPEI CITY (TW)

(72) Inventor: CHING-HUEI WU, NEW TAIPEI CITY (TW)

(21) Appl. No.: 13/920,276

(22) Filed: Jun. 18, 2013

(30) Foreign Application Priority Data
Apr. 9, 2013 (TW) 102206380

(51) Int. Cl. H01L 33/62

(52) U.S. Cl. CPC H01L 33/62
USPC 257/98

(57) ABSTRACT

Disclosed is a double-chip LED including a leadframe, a green chip, a blue chip, a transparent colloid and a red fluorescent layer. The green chip is installed at the bottom of the leadframe; the blue chip is installed at the bottom of the leadframe and adjacent to the green chip; the transparent colloid is sprayed or coated onto the green chip and the blue chip; and the red fluorescent layer is disposed on the transparent colloid and excited by a green light source or a blue light source to produce a mixed light source. The red fluorescent layer can be a red fluorescent plate or red fluorescent powder. In the present double-chip LED, the green chip and the blue chip excite the red fluorescent plate or red fluorescent powder to produce a better white light mixing effect.

### CROSS-REFERENCE TO RELATED APPLICATIONS

This non-provisional application claims priority under 35 U.S.C. §119(a) on Patent Application No(s). 102206380 filed in Taiwan, R.O.C. on Apr. 9, 2013, the entire contents of which are hereby incorporated by reference.

### BACKGROUND OF THE INVENTION

1. Field of the Invention

The present invention relates to a light emitting diode (LED), and more particularly to a double-chip LED that produces a better white light mixing effect by a red fluorescent layer.

2. Description of the Related Art

The structure of a conventional light emitting diode (LED) is comprised of components including chip, package, gold wire and leadframe, and the light emitting source comes from the chip installed inside the package. The chip produces a light source of different wavelengths according to different materials, and the conventional LED can emit a red light, reddish orange light, orange light, yellow light, yellowish green light, green light, blue light or white light, etc. Wherein, the white LED becomes a synonym of the 21^{st} century new-generation light source highly respected and well developed by the LED industry due to its advantages such as high efficiency, good durability, free of pollution, long service life, high shock resistance and low power consumption. The LED has been used extensively in different areas and gradually replaces the traditional light sources such as the incandescent lamps, fluorescent lamps, and high-pressure gas discharge lamps, etc.

However, LED is a monochrome light source, and thus the white light emitted from a white LED is actually formed by mixing a plurality of color lights, and a human visible white light is formed by at least two color lights of the aforementioned wavelengths. For example, the blue light and the yellow light are mixed to produce a white light of the aforementioned two wavelengths, or a blue light, a green light and a red light are mixed to obtain a white light of the aforementioned three wavelengths.

At present, the white LED available in the market is mainly divided into the following three types:

1. Red, blue, green LED chips are combined to produce a white LED. Since the chips emitting different color light sources are made of different materials, the voltage property varies. Therefore, the white LED of this sort incurs a higher cost and a more complicated design for the control circuit.

2. Nichia Corporation proposed a white LED manufactured by using a blue LED to excite yellow YAG phosphor. Compared with the yellow light, the blue light has a larger light emission spectrum range, and thus the color temperature is relatively higher and more uneven, and the wavelength of the light emitted from the blue light LED varies with an increase of temperature. As a result, it is difficult to control the white light source. In addition, the white LED of this sort lacks the light source of the red light waveband, thus causing a lower overall color rendering effect.

3. Ultraviolet LED is provided for exciting a transparent optical plastic material containing blue, red and green phosphors, and the white light of the three wavelengths can be obtained by excitation. However, the ultraviolet may deteriorate the adhesive such as epoxy resin in the LED, thus giving rise to a higher level of difficulty for the manufacturing process and a shorter service life of the LED.

Therefore, it is an urgent and important issue for related manufacturers to design and develop a double-chip LED that uses a double-chip grain to emit a light source and excite a red fluorescent plate or a red phosphor and changes the structure of the red fluorescent plate or the red phosphor to produce a better mixed light source and meet the market requirements.

### SUMMARY OF THE INVENTION

In view of the problems of the prior art, it is a primary objective of the present invention to overcome the problems of the prior art by providing a double-chip LED that adopts a red fluorescent layer to produce a better white light mixing effect, and adjusts the position of the red fluorescent layer according to different light mixing requirements.

To achieve the aforementioned objective, the present invention provides a double-chip LED comprising a leadframe, a green chip, a blue chip, a transparent colloid and a red fluorescent layer. The leadframe has an accommodating space. The green chip is installed at the bottom of the accommodating space for emitting a green light. The blue chip is installed at the bottom of the accommodating space and adjacent to the green chip for emitting a blue light. The transparent colloid is sprayed or coated onto the green chip and the blue chip, wherein the transparent colloid and the green chip or the blue chip have a height m, and m>0. The red fluorescent layer is a red fluorescent plate attached onto the transparent colloid and excited by the green light or the blue light to produce a mixed light.

Wherein, the red fluorescent layer is a red fluorescent plate attached onto the transparent colloid, and the red fluorescent plate is excited to emit a light with a wavelength λ_{R}, and 600 nm≦λ_{R}≦670 nm, and the red fluorescent plate has a distance h from the green chip, the blue chip, or a combination of both, and 0<h≦10 mm.

Preferably, the green light emitted from the green chip of the present invention has a wavelength λ_{G}, and 500 nm≦λ_{G}≦540 nm. The blue light emitted from the blue chip has a wavelength λ_{B}, and 380 nm≦λ_{B}≦470 nm.

To achieve the aforementioned objective, the present invention further provides a double-chip LED comprising a leadframe, a green chip, a blue chip, a transparent colloid and a red fluorescent layer. The leadframe has an accommodating space.

The green chip is installed at the bottom of the accommodating space for emitting a green light. The blue chip is installed at the bottom of the accommodating space and adjacent to the green chip for emitting a blue light. The transparent colloid is sprayed or coated onto the green chip and the blue chip, wherein the transparent colloid and the green chip or the blue chip have a height m and m>0. The red fluorescent layer is a red fluorescent powder sprayed onto the transparent colloid and excited by the green light or the blue light to produce a mixed light.

Wherein, the red fluorescent powder is excited to emit a light with a wavelength λ_{R}, and 600 nm≦λ_{R}≦670 nm.

Preferably, the green light source emitted from the green chip of the present invention has a wavelength λ_{G}, and 500 nm≦λ_{G}≦540 nm. The blue light source emitted from the blue chip has a wavelength λ_{B}, and 380 nm≦λ_{B}≦470 nm.

Different implementation modes can be adopted according to the different positions of the red fluorescent layer. Preferably, the red fluorescent layer completely covers the green chip and the blue chip, and the green light and the blue light excite the red fluorescent layer to produce a white light. Alternatively, the red fluorescent layer can cover either the green chip or the blue chip, and the green light emitted from the green chip or the blue light emitted from the blue chip excites the red fluorescent layer to produce a white light. In addition, a bump can be formed at the bottom of the leadframe and disposed between the green chip and the blue chip for separating the green chip and the blue chip.

The aforementioned and other objectives, technical characteristics and advantages of the present invention will become apparent with the detailed description of preferred embodiments and the illustration of related drawings as follows.

### BRIEF DESCRIPTION OF THE DRAWINGS

FIG. 1 is a schematic view of a double-chip LED of a first preferred embodiment of the present invention;

FIG. 2 is a schematic view of a double-chip LED of a second preferred embodiment of the present invention;

FIG. 3 is a schematic view of a double-chip LED of a third preferred embodiment of the present invention;

FIG. 4 is a schematic view of a double-chip LED of a fourth preferred embodiment of the present invention;

FIG. 5 is a schematic view of a double-chip LED of a fifth preferred embodiment of the present invention;

FIG. 6 is a schematic view of a double-chip LED of a sixth preferred embodiment of the present invention;

FIG. 7 is a schematic view of a double-chip LED of a seventh preferred embodiment of the present invention; and

FIG. 8 is a schematic view of a double-chip LED of an eighth preferred embodiment of the present invention.

### DETAILED DESCRIPTION OF THE PREFERRED EMBODIMENTS

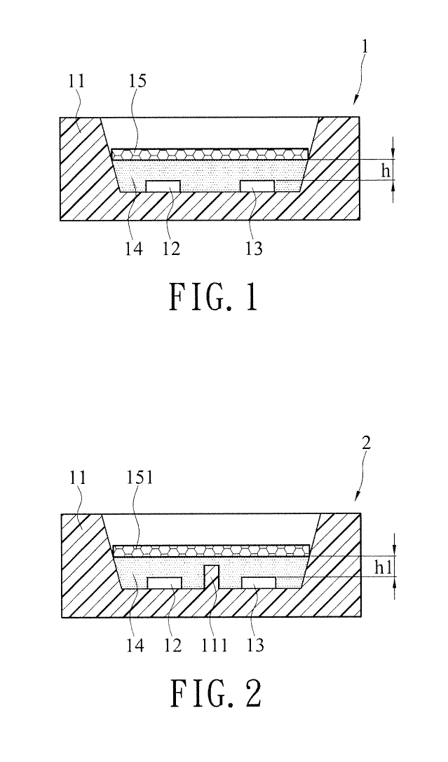

With reference to FIGS. 1 to 4 for schematic views of a double-chip LED in accordance with the first to fourth preferred embodiments of the present invention respectively. The double-chip LED comprises a leadframe 11, a green chip 12, a blue chip 13, a transparent colloid 14 and a red fluorescent layer 15. The leadframe 11 has an accommodating space for containing the green chip 12 and the blue chip 13. The green chip 12 is installed at the bottom of the accommodating space for emitting a green light; and the blue chip 13 is installed at the bottom of the accommodating space and adjacent to the green chip 12 for emitting a blue light. The transparent colloid 14 is sprayed or coated onto the green chip 12 and the blue chip 13, and the red fluorescent layer 15 of the second to fourth preferred embodiments can be a red fluorescent plate 151, 152, 153 installed on the transparent colloid 14 for receiving the green light or the blue light and being excited, thus, mixing the light to produce a white light. For simplicity, same numerals used in the following preferred embodiments represent same respective elements.

With reference to FIG. 1 for a schematic view of a double-chip LED in accordance with the first preferred embodiment of the present invention. The double-chip LED 1 has a red fluorescent layer 15 attached onto the transparent colloid 14, and the red fluorescent layer 15 emits a light with a wavelength λ_{R}, and 600 nm≦λ_{R}≦670 nm. The green chip 12 and the blue chip 13 are installed at the bottom of the leadframe 11, and the green chip 12 emits the green light source with a wavelength λ_{G}, and 500 nm≦λ_{G}≦540 nm; and the blue chip 13 emits the blue light source with a wavelength λ_{B}, and 380 nm≦λ_{B}≦470 nm.

Wherein, the red fluorescent layer 15 is completely covered onto light emitting surfaces of the green chip 12 and the blue chip 13 and attached onto inner sidewalls of the leadframe 11, so that the red fluorescent layer 15 can be excited by the green light source and the blue light source completely to produce a white light.

In FIG. 1, a distance h exists between the red fluorescent layer 15 and the green chip 12 or the blue chip 13, and preferably 0<h≦10 mm. The transparent colloid 14 is made of a transparent plastic material such as epoxy resin or silicone and sprayed or coated onto the green chip 12 and the blue chip 13 to prevent attaching directly with the red fluorescent layer 15.

With reference to FIG. 2 for a schematic view of a double-chip LED in accordance with the second preferred embodiment of the present invention. The difference of the double-chip LED 2 of the present invention from the double-chip LED 1 of the first preferred embodiment resides on that a bump 111 is formed at the bottom of the leadframe 11 and disposed between the green chip 12 and the blue chip 13 for separating the green chip 12 and the blue chip 13, so that the green light and the blue light can be emitted separately and respectively from the green chip 12 and the blue chip 13. The bump 11 has a height corresponding to the installation positions of the green chip 12 and the blue chip 13. The scale of the height given in the figure is provided for the purpose of illustration only, but not intended for limiting the scope of the invention.

Compared with the position of the red fluorescent layer 15 as shown in FIG. 1, a red fluorescent plate 151 of this preferred embodiment is attached onto the transparent colloid 14, and the red fluorescent plate 151 has a height h1 from the green chip 12 or the blue chip 13, and the distance hl preferably satisfies the condition of 0<h1≦10 mm.

After the transparent colloid 14 is installed, the transparent colloid 14 is baked and attached onto the red fluorescent plate 151, and then baked again to form a double-chip LED 2; or the transparent colloid 14 is installed and then attached directly onto the red fluorescent plate 151.

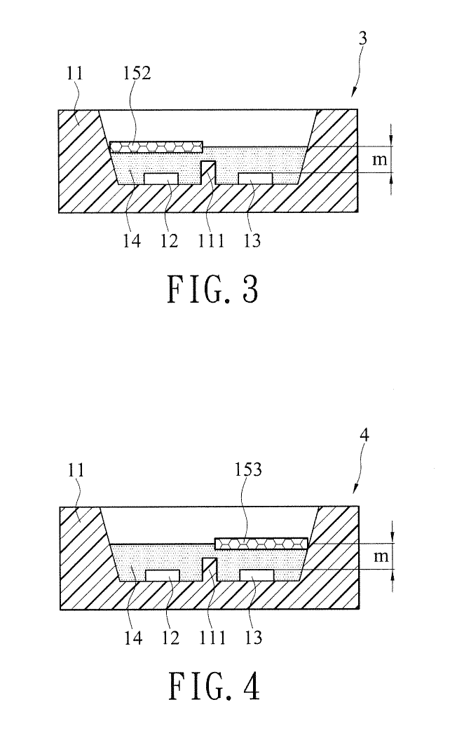

With reference to FIG. 3 for a schematic view of a double-chip LED in accordance with the third preferred embodiment of the present invention. The difference of the double-chip LED 3 of the third preferred embodiment from the double-chip LED 2 of the second preferred embodiment resides on that the double-chip LED 3 has the red fluorescent plate 152 installed on the green chip 12 for receiving the green light emitted from the green chip 12. In addition, the light emitted by exciting the red fluorescent plate 152 is mixed with the blue light emitted by the blue chip 13 adjacent to the green chip 12 to produce a white light with a better light mixing effect.

Wherein, the transparent colloid 14 is still disposed between the green chip 12, the blue chip 13 and the red fluorescent plate 152, and the transparent colloid has a height m, and m>0.

With reference to FIG. 4 for a schematic view of a double-chip LED in accordance with the fourth preferred embodiment of the present invention. The difference of the double-chip LED 4 of the fourth preferred embodiment from the double-chip LED 2 of the second preferred embodiment resides on that the double-chip LED 4 has the red fluorescent plate 153 installed on the blue chip 13 for receiving the blue light emitted from the blue chip 13. In addition, the light emitted by exciting the red fluorescent plate 153 is mixed with the green light emitted from the green chip 12 adjacent to the blue chip 13 to produce a white light with a better light mixing effect.

Wherein, the transparent colloid 14 is still disposed between the green chip 12, the blue chip 13 and the red fluorescent plate 152, and the transparent colloid has a height m, and m>0.

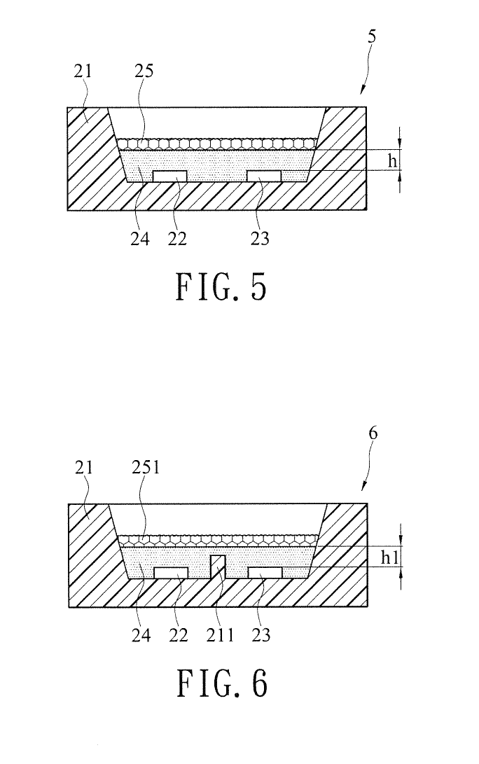

With reference to FIGS. 5 to 8 for schematic views of a double-chip LED in accordance with the fifth preferred embodiment to the eighth preferred embodiment of the present invention respectively, the double-chip LED comprises a leadframe 21, a green chip 22, a blue chip 23, a transparent colloid 24 and a red fluorescent layer 25. The leadframe 21 includes the green chip 22 and the blue chip 23 installed therein. The green chip 22 is installed at the bottom of the leadframe 21 for emitting a green light; and the blue chip 23 is installed at the bottom of the leadframe 21 and adjacent to the green chip 22 for emitting a blue light. The transparent colloid 24 is sprayed or coated onto the green chip 22 and the blue chip 23, wherein the red fluorescent layer 25 of the sixth preferred embodiment to the eighth preferred embodiment can be a red fluorescent powder 251, 252, 253 sprayed or vapor deposited onto the transparent colloid 24 for receiving the green light, the blue light or their combination and excited to emit a light, and mixing the lights to produce a white light. For simplicity, same numerals used in the following preferred embodiments represent same respective elements.

With reference to FIG. 5 for a schematic view of a double-chip LED in accordance with the fifth preferred embodiment of the present invention. The double-chip LED 5 has the red fluorescent layer 25 sprayed or vapor deposited uniformly onto the transparent colloid 24, and the red fluorescent layer 25 emits a light with a wavelength λ_{R}, and 600 nm≦λ_{R}≦670 nm. The green chip 22 and the blue chip 23 are installed at the bottom of the leadframe 21, and the green chip 22 emits the green light with a wavelength λ_{G}, and 500 nm≦λ_{G}≦540 nm; and the blue chip 23 emits the blue light with a wavelength λ_{B}, and 380 nm≦λ_{B}≦470 nm.

Wherein, the red fluorescent layer 25 is completely covered onto the green chip 22 and the blue chip 23 for receiving the green light and the blue light emitted from the green chip 22 and the blue chip 23 respectively, so that the red fluorescent layer 25 can be excited by the green light and the blue light completely to produce a white light with a better light mixing effect.

In FIG. 5, a distance h exists between the red fluorescent layer 25 and the green chip 22 or the blue chip 23, and preferably the distance h satisfies the condition of 0<h≦10 mm. The transparent colloid 24 is made of a transparent plastic material such as epoxy resin or silicone and sprayed or coated onto the green chip 22 and the blue chip 23 to prevent a direct contact with the red fluorescent layer 25.

With reference to FIG. 6 for a schematic view of a double-chip LED in accordance with the sixth preferred embodiment of the present invention. The difference of the double-chip LED 6 of the present invention from the double-chip LED 5 of the fifth preferred embodiment resides on that a bump 211 is formed at the bottom of the leadframe 21 and disposed between the green chip 22 and the blue chip 23 for separating the green chip 22 and the blue chip 23, so that the green light and the blue light can be emitted from the green chip 22 and the blue chip 23 respectively and separately. The height of the bump 21 corresponds to the installation positions of the green chip 22 and the blue chip 23. The scale of the height given in the figure is provided for the purpose of illustration only, but not intended for limiting the scope of the invention.

Compared with the position of the red fluorescent layer 25 as shown in FIG. 5, a red fluorescent plate 251 of this preferred embodiment is sprayed or vapor deposited uniformly onto the transparent colloid 24, and the red fluorescent plate 251 has a height h1 from the green chip 22 or the blue chip 23, and the distance h1 preferably satisfies the condition of 0<h1≦10 mm.

After the transparent colloid 24 is formed on the green chip 22 and the blue chip 23, the transparent colloid 24 is baked and the red fluorescent powder 251 is sprayed or vapor deposited and then baked again and cured to form a double-chip LED 6. Alternatively, the transparent colloid 24 is applied and then the red fluorescent powder 251 is sprayed or vapor deposited directly onto the transparent colloid 24, and then baked to cure the red fluorescent powder 251.

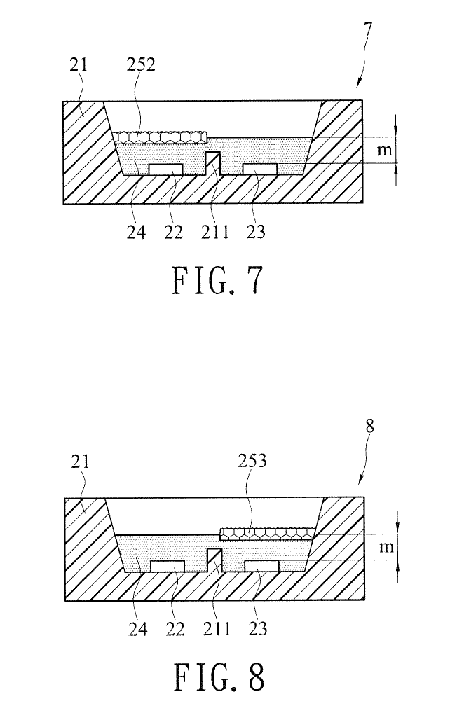

With reference to FIG. 7 for a schematic view of a double-chip LED in accordance with the seventh preferred embodiment of the present invention. The difference of the double-chip LED 7 of the seventh preferred embodiment from the double-chip LED 6 of the sixth preferred embodiment resides on that the double-chip LED 7 has the red fluorescent powder 252 installed on the green chip 22 for receiving the green light source emitted from the green chip 22. In addition, the light emitted by exciting the red fluorescent powder 252 is mixed with the blue light emitted from the blue chip 23 adjacent to the green chip 22 to produce a white light with a better light mixing effect.

Wherein, the transparent colloid 24 is still disposed between the green chip 22, the blue chip 23 and the red fluorescent powder 252, and the transparent colloid has a height m, and m>0.

With reference to FIG. 8 for a schematic view of a double-chip LED in accordance with the eighth preferred embodiment of the present invention. The difference of the double-chip LED 8 of the eighth preferred embodiment from the double-chip LED 6 of the sixth preferred embodiment resides on that the double-chip LED 8 has the red fluorescent powder 253 installed on the blue chip 23 for receiving the blue light emitted from the blue chip 23. In addition, the light emitted by exciting the red fluorescent powder 253 is mixed with the green light emitted from the green chip 22 adjacent to the blue chip 23 to produce a white light with a better light mixing effect.

Wherein, the transparent colloid 24 is disposed between the green chip 22, the blue chip 23 and the red fluorescent powder 252 of the present invention, and the transparent colloid has a height m, and m>0.

1. A double-chip light emitting diode (LED), comprising:
a leadframe;
a green chip, installed at the bottom of the leadframe, for emitting a green light;
a blue chip, installed at the bottom of the leadframe and adjacent to the green chip, for emitting a blue light;
a transparent colloid, sprayed or coated onto the green chip and the blue chip; and
a red fluorescent layer, disposed on the transparent colloid, and excited by the green light or the blue light to produce a mixed light,
wherein the red fluorescent plate has a distance h from the green chip, the blue chip, or a combination of both, and h is approximately 10 mm, and the leadframe has a bump formed at the bottom of the leadframe and disposed between the green chip and the blue chip for separating the green chip and the blue chip, the red fluorescent layer is disposed on the blue chip for receiving a light emitted from one of the green chip or the blue chip.

2. The double-chip LED of claim 1, wherein the red fluorescent layer is a red fluorescent plate attached onto the transparent colloid, and the red fluorescent plate is excited to emit a light with a wavelength λ_{R}, and 600 nm≦λ_{R}≦670 nm.

3. (canceled)

4. The double-chip LED of claim 1, wherein the red fluorescent layer is a red fluorescent powder sprayed or vapor deposited on the transparent colloid, and the red fluorescent powder is excited to emit a light with a wavelength λ_{R}, and 600 nm≦λ_{R}≦670 nm.

5. (canceled)

6. (canceled)

7. The double-chip LED of claim 1, wherein the green chip emits the green light with a wavelength λ_{G}, and 500 nm≦λ_{G}≦540 nm.

8. The double-chip LED of claim 1, wherein the blue chip emits the blue light with a wavelength λ_{B}, and 380 nm≦λ_{B}≦470 nm.

9. The double-chip LED of claim 1, wherein the transparent colloid and the green chip or the blue chip have a height m, and m>0.

10. (canceled)
